(19) United States
(12) Patent Application Publication
(10) Pub. No.: US 2025/0166676 A1
(43) Pub. Date: May 22, 2025

(54) DATA STROBE TOGGLING BY A CONTROLLER

(71) Applicant: Micron Technology, Inc., Boise, ID (US)

(72) Inventor: Leonid Minz, Beer Sheva (IL)

(21) Appl. No.: 18/946,242

(22) Filed: Nov. 13, 2024

Related U.S. Application Data
(60) Provisional application No. 63/602,057, filed on Nov. 22, 2023.

(51) Int. Cl. G11C 7/10; G11C 7/22

(52) U.S. Cl. CPC G11C 7/1066; G11C 7/1063; G11C 7/222

(57) ABSTRACT

A method includes providing a first plurality of data signals and a first plurality of clock signals to a flip-flop circuit to generate a first plurality of outputs corresponding to the first plurality of data signals and the first plurality of clock signals, providing the first plurality of outputs to a first-in first-out (FIFO) device, providing a second plurality of data signals to the flip-flop circuit, providing a second plurality of clock signals generated by a controller to the flip-flop circuit, and providing a second plurality of outputs corresponding to the second plurality of data signals and the second plurality of clock signals to move the first plurality of outputs through the FIFO device.

### PRIORITY INFORMATION

This application claims the benefit of U.S. Provisional Application No. 63/595,589, filed on Nov. 22, 2023, the contents of which are incorporated herein by reference.

### TECHNICAL FIELD

Embodiments of the disclosure relate generally to memory sub-systems, and more specifically, relate to data strobe (DQS) toggling by a controller.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the disclosure.

FIG. 2 illustrates system for DQS toggling by a controller in accordance with some embodiments of the disclosure.

FIG. 3 is a flow diagram corresponding to a method for independent sensing times in accordance with some embodiments of the disclosure.

FIG. 4 is a block diagram of an example computer system in which embodiments of the disclosure may operate.

### DETAILED DESCRIPTION

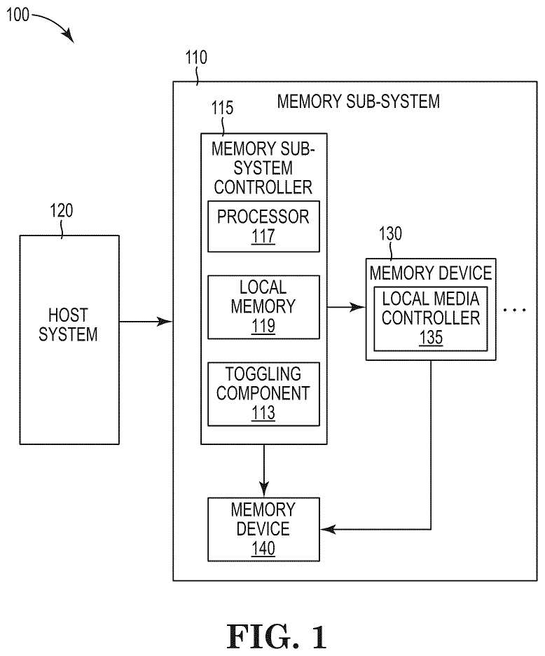

Aspects of the present disclosure are directed to data strobe pin (DQS) toggling by a controller, in particular to memory sub-systems that include a toggling component. A memory sub-system can be a storage system, storage device, a memory module, or a combination of such. An example of a memory sub-system is a storage system such as a solid-state drive (SSD). Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system.

A memory device can be a non-volatile memory device. One example of non-volatile memory devices is a negative-and (NAND) memory device (also known as flash technology). As used herein, a NAND memory device can include either a set of flash memory dice or a combination of the flash memory dice and a non-volatile memory (NVM) controller. The NVM controller can include circuitry for performing read/write operations as described herein. Other examples of non-volatile memory devices are described below in conjunction with FIG. 1. A non-volatile memory device is a package of one or more dice. Each die can consist of one or more planes. Planes can be grouped into logic units (LUN). For some types of non-volatile memory devices (e.g., NAND devices), each plane consists of a set of physical blocks. Each block consists of a set of pages. Each page consists of a set of memory cells (“cells”). A cell is an electronic circuit that stores information. A block hereinafter refers to a unit of the memory device used to store data and can include a group of memory cells, a word line group, a word line, or individual memory cells. For some memory devices, blocks (also hereinafter referred to as “memory blocks”) are the smallest area that can be erased. Pages cannot be erased individually, and only whole blocks can be erased.

Each of the memory devices can include one or more arrays of memory cells. Depending on the cell type, a cell can be written to in order to store one or more bits of binary information, and has various logic states that correlate to the number of bits being stored. The logic states can be represented by binary values, such as “0” and “1”, or combinations of such values. There are various types of cells, such as single-level cells (SLCs), multi-level cells (MLCs), triple level cells (TLCs), and quad-level cells (QLCs). For example, a SLC can store one bit of information and has two logic states.

Some NAND memory devices employ a floating-gate architecture in which memory accesses are controlled based on a relative voltage change between the bit line and the word lines. Other examples of NAND memory devices can employ a replacement-gate architecture that can include the use of word line layouts that can allow for charges corresponding to data values to be trapped within memory cells based on properties of the materials used to construct the word lines.

In some previous approaches, a first-in, first-out (FIFO) device can be utilized to buffer communication between a memory device and a controller during read operations and/or write operations. A FIFO device can be utilized to buffer communication signals between devices that operate at different speeds or utilize independent clock signals. The FIFO device can be utilized to increase bandwidth and prevent data loss during high-speed communications. In some embodiments, a FIFO device can release data from the buffer in the order of its arrival. That is, a signal can be provided to an input of a FIFO device and be released at an output of the FIFO device in the order it was received at the input of the FIFO device.

In such approaches, the input of the FIFO device can be coupled to a flip-flop circuit. In general, a flip-flop circuit or latch circuit is a circuit that has two stable states and can be used to store state information. The flip-flop circuit can be made to change state by signals applied to one or more control inputs and will have one or two outputs. In this way, the flip-flop circuit can change state information each time a signal is received at the input of the flip-flop circuit. In some embodiments, the FIFO device can include a plurality of stages or storage locations to store a signal received at the input of the FIFO device from an output of the flip-flop circuit. The plurality of stages can each be utilized to store a corresponding state based on a signal received. When the FIFO device receives an additional signal, the previous signal is moved to the next stage until the signal is moved to the output of the FIFO device. In this way, a signal received at the input of the FIFO device can be “pushed” through each of the plurality of stages when additional signals are received at the input of the FIFO device from the flip-flop circuit until the signal is directed to an output of the FIFO device.

In previous approaches, the FIFO device is positioned within the physical layer (PHY) of the memory device. In these approaches, data signals (DQ signals) can be provided by a memory device such as a NAND device. Furthermore, strobe signals (DQS signals) can be provided by a controller device. The DQS signals can be generated for each DQ signal provided by the memory device. In this way, output data can be generated at the flip-flop circuit based on the received DQ signal and DQS signal at the flip-flop circuit. The output data can be provided to the FIFO device to be provided to a controller in an order it was received at the FIFO device. In some embodiments, output data, DQ signals, and/or DQS signals can be trapped within the flip-flop circuit and/or FIFO device when the memory device and/or controller stop providing signals to the input of the flip-flop circuit. In this way, a delay can occur in processing the DQ signals from the memory device.

Aspects of the present disclosure address the above and other deficiencies by employing DQS toggling by a controller. For instance, the present disclosure can utilize a plurality of flip-flop circuits inside the PHY that are coupled to pipeline stages of a FIFO device placed outside the PHY or within an ASIC voltage domain. This configuration can allow for increased real estate for the FIFO device compared to other configurations, such as those employed in previous approaches. As used herein, the real estate refers to a physical area for positioning components on a memory device. In these embodiments, the controller can generate extra DQS signals that are used to push data through the flip-flop circuits and the pipeline stages of the FIFO device. The controller can then send instructions to the NAND device to generate extra DQ signals that correspond to the extra DQS signals. In this way, the data corresponding to the DQ signals that remain in the FIFO device can be pushed through the FIFO device to be processed. In these embodiments, the extra DQ signals and DQS signals can be flagged to be ignored as “garbage data” when processed since the DQ signals do not correspond to data stored on the NAND device.

FIG. 1 illustrates an example computing system 100 that includes a memory sub-system 110 in accordance with some embodiments of the disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single-level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, a MLC portion, a TLC portion, a QLC portion, and/or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

As described above, the memory components can be memory dice or memory packages that form at least a portion of the memory device 130. In some embodiments, the blocks of memory cells can form one or more “superblocks.” As used herein, a “superblock” generally refers to a set of data blocks that span multiple memory dice and are written in an interleaved fashion. For instance, in some embodiments each of a number of interleaved NAND blocks can be deployed across multiple memory dice that have multiple planes and/or pages associated therewith. The terms “superblock,” “block,” “block of memory cells,” and/or “interleaved NAND blocks,” as well as variants thereof, can, given the context of the disclosure, be used interchangeably.

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. The memory sub-system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140. For instance, in some embodiments, the memory device 140 can be a DRAM and/or SRAM configured to operate as a cache for the memory device 130. In such instances, the memory device 130 can be a NAND.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local media controller 135) for media management within the same memory device package. An example of a managed memory device is a managed NAND (MNAND) device. The memory sub-system 110 can also include additional circuitry or components that are not illustrated.

The memory sub-system 110 can include a toggling component 113, which may be referred to in the alternative as a “controller,” herein. Although not shown in FIG. 1 so as to not obfuscate the drawings, the toggling component 113 can include various circuitry to facilitate aspects of media management, as detailed herein. In some embodiments, the toggling component 113 can include special purpose circuitry in the form of an ASIC, FPGA, state machine, and/or other logic circuitry that can allow the toggling component 113 to orchestrate and/or perform the operations described herein.

In some embodiments, the memory sub-system controller 115 includes at least a portion of the toggling component 113. For example, the memory sub-system controller 115 can include a processor 117 (processing device) configured to execute instructions stored in local memory 119 for performing the operations described herein. In some embodiments, the toggling component 113 is part of the memory sub-system 110, an application, or an operating system.

In a non-limiting example, an apparatus (e.g., the computing system 100) can include a toggling component 113. The toggling component 113 can be resident on the memory sub-system 110. As used herein, the term “resident on” refers to something that is physically located on a particular component. For example, the toggling component 113 being “resident on” the memory sub-system 110 refers to a condition in which the hardware circuitry that comprises the toggling component 113 is physically located on the memory sub-system 110. The term “resident on” can be used interchangeably with other terms such as “deployed on” or “located on,” herein.

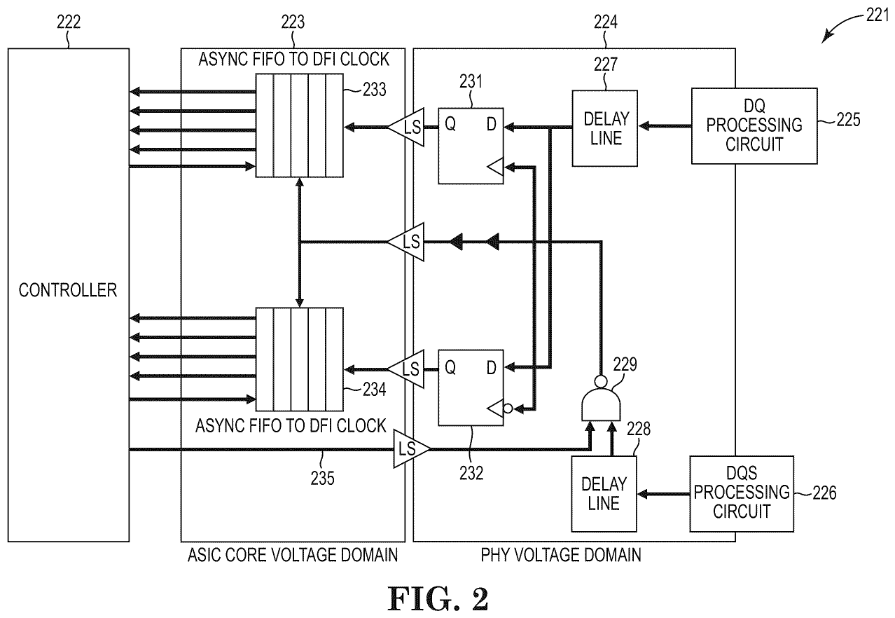

As described further herein with reference to FIG. 2, the memory sub-system 110 can include a first flip-flop circuit to receive data signals from a data processing circuit. In these embodiments, the memory sub-system 110 can include a second flip-flop circuit to receive clock signals from a clock processing circuit. In some embodiments, the memory sub-system 110 can include a first first-in first-out (FIFO) device to receive a first output data from the first flip-flop circuit and a second FIFO device to receive a second output data from the second flip-flop circuit. In this way, the input of the first flip-flop circuit can be coupled to a DQ processing circuit and the output of the first flip-flop circuit is coupled to an input of the first FIFO device. In addition, the input of the second flip-flop circuit can be coupled to a DQS processing circuit and the output of the second flip-flop circuit can be coupled to the second FIFO device.

The toggling component 113 can be configured to receive the first output data from the first FIFO device. The first output data from the first FIFO device can be output data that is pushed through the first flip-flop circuit and through the first FIFO device to the output of the first FIFO device. In these examples, the first output data from the first FIFO device can be based on signals received from a DQ processing circuit. As described herein, the first flip-flop circuit can change the state of a data value (e.g., a data value of a logical “1” or a logical “0”) when a signal (e.g., a clocking signal) is received at an input of the first flip-flop circuit. In this way, the DQ processing circuit can cause the state of the data value stored by the first flip-flop circuit to be altered (e.g., “flipped” or “flopped”) for each signal the DQ provides to the input of the flip-flop circuit.

As described herein, in order for the state (e.g., the logical value of “1” or “0”) of the first flip-flop circuit to be transferred to the input of the first FIFO device, the first flip-flop circuit needs to receive a subsequent signal. In this way, a state within the first flip-flop circuit may not be transferred to the first FIFO device if the DQ processing circuit does not provide an additional signal to the input of the first flip-flop circuit. As described herein, this can cause delays in some approaches when attempting to process the signals from the DQ processing circuit.

The toggling component 113 can be configured to receive the second output data from the second FIFO device. The second output data from the second FIFO device can be output data that is pushed through the second flip-flop circuit and through the second FIFO device. In some embodiments, a DQS processing circuit can provide a signal to an input of the second flip-flop circuit and an output signal of the second flip-flop circuit can be provided to the input of the second FIFO device.

As described herein, in order for the state of the second flip-flop circuit to be transferred to the input of the second FIFO device, the second flip-flop circuit needs to receive a subsequent signal. In this way, a state within the second flip-flop circuit may not be transferred to the second FIFO device if the DQS processing circuit does not provide an additional signal to the input of the second flip-flop circuit. As described herein, this can cause delays for previous approaches when attempting to process the signals from the DQS processing circuit.

The toggling component 113 can be configured to generate additional clock signals to be provided to the second flip-flop circuit to generate additional output data. The additional clock signals provided to the second flip-flop circuit can be signals generated by the toggling component 113. In some embodiments, the additional clock signals can be generated such that the additional clock signals do not correspond to data to be read or written by the memory device 103/140. That is, the data generated from the additional clock signals can be referred to as garbage data. As used herein, “garbage data” refers to data or signals that are flagged to be disregarded or ignored by a device, such as the memory device(s) 130/140.

In some embodiments, the additional clock signals can mimic the signals generated by the DQS processing circuit. In this way, the additional clock signals can be provided to the input of the second flip-flop circuit to move signals stored within the second flip-flop circuit to the input of the second FIFO device and push the data through the second FIFO device. In this way, DQS signals from the DQS processing circuit to be utilized for processing data that are stalled within the second flip-flop circuit and/or the FIFO device can be pushed through the memory device 130/140 to avoid a lag in processing the data.

In some embodiments, the toggling component 113 can be configured to instruct the memory device 130/140 (e.g., NAND, etc.) to generate and provide additional signals to the input of the first flip-flop circuit to correspond with the additional clock signals provided to the second flip-flop circuit by the toggling component 113. In this way, the output data stalled within the first flip-flop circuit and/or the second flip-flop circuit can be processed. In these embodiments, the additional signals provided to the first flip-flop circuit and the second flip-flop circuit can be flagged to be ignored or disregarded.

The toggling component 113 can be configured to notify a memory resource associated with the memory device 130 to ignore the additional output data. In some embodiments, the toggling component can generate a notification to be provided to the memory resource associated with the memory device 130. For example, the notification can indicate a particular flag or tag that is utilized to mark garbage data to be ignored. As described herein, the additional output data generated by the additional signals can be flagged or tagged to indicate that the additional output data is garbage data or data that is not to be utilized by the memory sub-system 110. That is, data from the additional clock signals provided to the first flip-flop circuit and/or second flip-flop circuit can be discarded or ignored instead of being processed.

FIG. 2 illustrates system 221 for DQS toggling by a controller 222 in accordance with some embodiments of the disclosure. In some embodiments, the system 221 can include similar components or elements as the memory system 110 of FIG. 1. In some embodiments, the controller 222 can be at least a portion of the toggling component 113 of FIG. 1.

The system 221 can include a PHY voltage domain 224 and an application-specific integrated circuit (ASIC) core voltage domain 223. As described herein, the PHY voltage domain 224 can be a physical layer of the electrical circuit of the system 221. In these embodiments, the ASIC core voltage domain 223 can include an integrated circuit customized for a specific purpose. In these embodiments, the system 221 can include a first FIFO device 233 and a second FIFO device 234 positioned (e.g., deployed) within the ASIC core voltage domain 223. In these embodiments, the system 221 includes a first flip-flop circuit 231 and a second flip-flop circuit 232 that are positioned on the PHY voltage domain 224. As described herein, previous approaches can position the first FIFO device 233 and the second FIFO device 234 within the PHY voltage domain. In this way, the present disclosure moves the first FIFO device 233 and the second FIFO device 234 from the PHY voltage domain 224 to the ASIC core voltage domain 223.

The system 221 can include a DQ processing circuit 225 to provide DQ signals from a NAND or other type of memory device. The DQ processing circuit 225 can comprise various hardware circuitry that can be configured to provide the DQ signals to a delay line 227. The delay line 227 can be an arbiter or similar circuitry to ensure that signals are not provided to a device simultaneously or substantially simultaneously. The DQ signals can be provided to the first flip-flop circuit 231 and/or the second flip-flop circuit 232. In some embodiments, the first flip-flop circuit 231 can store a first value corresponding to a first DQ signal received from the delay line 227. In these embodiments, the first flip-flop circuit 231 can provide the first value to the first FIFO device 233 upon receiving a second DQ signal received from the delay line 227. In this embodiment, the first flip-flop circuit 231 can store a second value corresponding to the second DQ signal and store the second value until a subsequent DQ signal is received by the first flip-flop circuit 231.

In a similar way, the system 221 can include a DQS processing circuit 226 to provide DQS signals from the controller 222. The DQS processing circuit 226 can comprise various hardware circuitry that can be configured to provide the DQS signals to a delay line 228. The delay line 228 can be an arbiter or similar circuitry to ensure that signals are not provided to a device simultaneously or substantially simultaneously. In some embodiments, the DQS signals from the delay line 228 are provided to a NAND gate 229 that can receive DQS signals from the DQS processing circuit 226 and/or the controller 222. In some embodiments, the controller 222 can be configured to generate a plurality of clock signals that correspond to a plurality of data signals received from the memory device. That is, the controller 222 can generate a clock signal for each data signal generated by the memory device (e.g., NAND device, etc.).

The DQS signals can be provided to the second flip-flop circuit 232 and/or the first flip-flop circuit 231. In some embodiments, the second flip-flop circuit 232 can store a first value of a first DQS signal received from the NAND gate 229. In these embodiments, the second flip-flop circuit 232 can provide the first value to the second FIFO device 234 upon receiving a second DQS signal received from the NAND gate 229. In this embodiment, the second flip-flop circuit 232 can store a second value corresponding to the second DQS signal and store the second value until a subsequent DQS signal is received by the second flip-flop circuit 232.

In some embodiments, the first FIFO device 233 and the second FIFO device 234 can include a number of stages such that data received at an input is transferred through each of the stages before being transferred out of the corresponding FIFO device to the controller 222. For example, the first FIFO device 233 can include four stages. Although four stages are described, any number of stages can be utilized in a similar way. In this example, the first FIFO device 233 can receive a first value (e.g., state) or first DQ signal from the first flip-flop circuit 231. The first value can be stored at a first stage of the first FIFO device 233. In this example, the first FIFO device can receive a second value (e.g., state) or second DQ signal from the first flip-flop circuit 231. The first FIFO device 233 can push the first value to the second stage and store the second value at the first stage. For each value received at the first FIFO device 233, the received value can be stored at the first stage and the other values can be pushed to the next stage until the value is pushed out of the fourth stage and to the controller 222. The second FIFO device 234 can operate in a similar way as the first FIFO device 233 when receiving DQS signals from the NAND gate 229.

In some embodiments, the controller 222 can be configured to identify an output value based on the plurality of data signals and the plurality of clock signals applied to a FIFO device. In some embodiments, the output value can be a value that is stalled or trapped within the FIFO device. The controller 222 may be able to identify a trapped output value within the FIFO device based on a quantity of data signals and clock signals provided to the DQ processing circuit 225 and DQS processing circuit 226 respectively. For example, the data signals and/or clock signals may be a quantity that will result in output data being trapped at a particular stage of the system 221. In some embodiments, the controller 222 can be configured to calculate a quantity of the additional clock signals based on a quantity of bits to be provided to the memory device and a quantity of bits utilized by the first FIFO device 233 and the second FIFO device 234.

In another example, the controller 222 may be able to identify a trapped output value when the NAND stops providing data signals to the DQ processing circuit 225. For example, the controller 222 can be configured to identify a last clock signal from the memory device and determine a quantity of additional clock signals to generate based on a quantity of bits within FIFO device and a size of the FIFO device. As described herein, the size of the FIFO device can correspond to a maximum quantity of storage locations of the FIFO device and/or a quantity of stages associated with the FIFO device. In this way, the controller 222 can determine a quantity of additional clock signals and data signals needed to push the trapped data within the FIFO device out of the FIFO device.

In some embodiments, the controller 222 can be configured to generate additional clock signals when the memory device has completed sending the plurality of data signals. In these embodiments, the controller 222 can send the additional clock signals to the FIFO device (e.g., second FIFO device 234) through the second flip-flop circuit 232. As described further herein, the controller 222 can be configured to instruct the memory device to provide additional data signals to the FIFO device (e.g., first FIFO device 233) through the first flip-flop circuit 231 based on the additional clock signals.

As described herein, the process of pushing DQ signals through the first flip-flop circuit 231 and first FIFO device 233 to the controller 222 and pushing the DQS signals through the second flip-flop circuit 232 and the second FIFO device 234 can traditionally result in data being stalled within one or more of the first flip-flop circuit 231, first FIFO device 233, second flip-flop circuit, and/or the second FIFO device 234. For this reason, the present disclosure can utilize the controller 222 to provide additional DQS signals to the NAND gate 229 through connection 235. In these embodiments, the additional DQS signals from the controller 222 to the NAND gate 229 may correspond to data that is to be ignored or identified as garbage data. The additional DQS signals from the controller 222 through the connection 235 can be utilized to push stalled data through the second flip-flop circuit 232 and/or the second FIFO device 234.

In some embodiments, the controller 222 can determine a quantity of additional DQS signals to provide based on a quantity of data stalled within the second flip-flop circuit 232 and/or the second FIFO device 234. That is, the controller 222 can determine a quantity of additional DQS signals needed to push a last received DQS signal from the DQS processing circuit 226 through the second flip-flop circuit 232 and/or the second FIFO device 234. In some embodiments the additional DQS signals can be tagged or flagged by the controller 222 as non-usable signals or signals to be ignored.

In some embodiments, the controller 222 can send a signal or communication to the NAND or memory device providing the DQ signals to the DQ processing circuit. In these embodiments, the controller 222 can send a communication signal to the NAND to generate additional DQ signals to the DQ processing circuit 225. In some embodiments, the quantity of additional DQ signals generated by the NAND or memory device can be the same or similar quantity as the quantity of additional DQS signals generated by the controller 222 and provided to the NAND gate 229. In a similar way as the additional DQS signals, the additional DQ signals can be utilized to push stalled data within the first flip-flop circuit 231 and/or the first FIFO device 233. In addition, the additional DQ signals can be flagged or tagged as signals to be ignored or prevented from being processed.

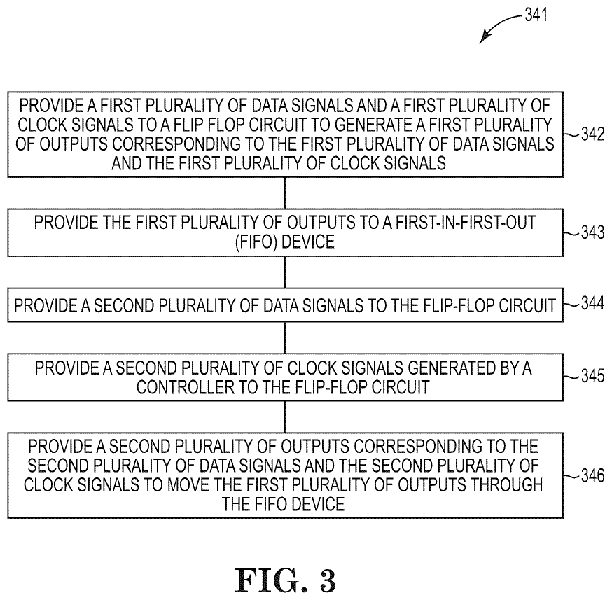

FIG. 3 is a flow diagram corresponding to a method 341 for DQS toggling in accordance with some embodiments of the disclosure. The method 341 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 341 is performed by the toggling component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 342, the method 341 can be executed to provide a first plurality of data signals and a first plurality of clock signals to a flip-flop circuit to generate a first plurality of outputs corresponding to the first plurality of data signals and the first plurality of clock signals. As used herein, a data signal can refer to a DQ signal provided by a NAND device or other type of memory storage device. As described herein, the DQ signal can be provided to a DQ processing circuit 225 of FIG. 2 and provided to a first flip-flop circuit 231 of FIG. 2. As used herein, a clock signal can refer to a DQS signal provided by a controller. As described herein, the DQS signal can be provided to a DQS processing circuit 226 of FIG. 2 and provided to a second flip-flop circuit 232 of FIG. 2.

In some embodiments, the data signal is compared to the clock signal to determine an output based on the comparison. In these embodiments, the data signal and the clock signal can be provided to an input of a flip-flop circuit to generate a particular state or output within the flip-flop circuit based on the values of the data signal and clock signal. As described herein, the state or output of the flip-flop circuit can be transferred to a FIFO device when a subsequent data signal and/or clock signal is received at the input of the flip-flop circuit. In some embodiments, the first plurality of outputs include data outputs to be utilized by a controller. For example, the first plurality of outputs can include data to be read from the NAND device that includes data signals from the NAND device. In this way, the data signals correspond to data stored within the NAND device.

At operation 343, the method 341 can be executed to provide the first plurality of outputs to a first-in first-out (FIFO) device. As described herein, the first plurality of outputs that correspond to data stored within the NAND device can be provided to a first FIFO device. The FIFO device can receive the first plurality of outputs and provide the outputs to a controller based on the order the first plurality of outputs were received. As described herein, a portion of the first plurality of outputs can be trapped within the flip-flop circuit and/or the first FIFO device when there are no additional data signals or clock signals to push the output data through the flip-flop circuit and/or FIFO device. In these embodiments, additional clock signals and/or data signals can be generated to push the trapped data through the flip-flop circuit and/or FIFO device.

At operation 344, the method 341 can be executed to provide a second plurality of data signals to the flip-flop circuit. In some embodiments, the second plurality of data signals can be signals that do not correspond to data stored within the NAND device. In some embodiments, a controller can instruct the NAND device to send the second plurality of data signals in response to determining that output data from the first plurality of data signals are trapped within the flip-flop circuit and/or FIFO device. For example, the controller can determine a quantity of data signals needed to push the remaining output data from the first plurality of data signals through the flip-flop circuit and/or FIFO device. In this example, the controller can instruct the NAND device to generate the second plurality of data signals to include the determined quantity.

At operation 345, the method 341 can be executed to provide a second plurality of clock signals generated by a controller to the flip-flop circuit. In some embodiments, the second plurality of clock signals can be generated by the controller and provided to the DQS processing circuit and/or provided directly to a NAND switch device such that the second plurality of clock signals are utilized to push the remaining output data from the first plurality of data signals through the flip-flop circuit and/or FIFO device. As described herein, the second plurality of clock signals may not correspond to data that is to be read from the NAND device. For this reason, the second plurality of clock signals can be flagged or identified to be ignored. In this way, output data generated from the second plurality of data signals and the second plurality of clock signals can be identified as garbage data or data that is to be ignored.

At operation 346, the method 341 can be executed to provide a second plurality of outputs corresponding to the second plurality of data signals and the second plurality of clock signals to move the first plurality of outputs through the FIFO device. As described herein, the second plurality of outputs corresponding to the second plurality of data signals and the second plurality of clock signals can be referred to as garbage data since the second plurality of outputs do not correspond to data stored within the NAND device. The second plurality of outputs can push the trapped output data from the first plurality of outputs through the flip-flop circuit and FIFO device such that garbage outputs from the second plurality of outputs are trapped within the flip-flop circuit and FIFO device.

In this way, a data gap can be generated utilizing the additional clock signals and/or additional data signals. For example, the garbage outputs do not correspond to data within the NAND device and thus can be referred to as a gap in data from the NAND. The data gap can be utilized to push the data from the NAND device through the flip-flop circuit and FIFO device to allow the data to be processed when there is a delay in additional data signals being provided to a DQ processing circuit that correspond to actual NAND device data.

As described herein, the second plurality of outputs can be flagged as garbage data such that the second plurality of outputs are ignored by the controller. In this way, the portion of the second plurality of outputs that are trapped within the flip-flop circuit and FIFO device can be ignored when non-garbage data or data from the NAND pushes the portion of the second plurality of outputs through the flip-flop circuit and FIFO device. Thus, the data to be read from the NAND can be pushed through the flip-flop circuit and FIFO device and avoid delays while garbage data from the second plurality of outputs can be trapped within the flip-flop circuit and FIFO device.

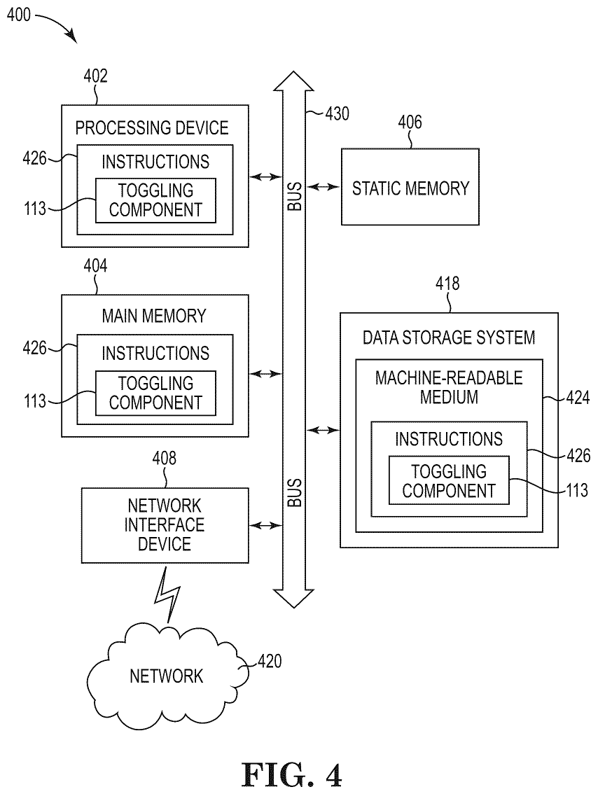

FIG. 4 is a block diagram of an example computer system 400 in which embodiments of the disclosure may operate. For example, FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the toggling component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a data storage system 418, which communicate with each other via a bus 430.

The processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a toggling component (e.g., the toggling component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer).

In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc. In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
providing a first plurality of data signals and a first plurality of clock signals to a flip-flop circuit to generate a first plurality of outputs corresponding to the first plurality of data signals and the first plurality of clock signals;
providing the first plurality of outputs to a first-in first-out (FIFO) device;
providing a second plurality of data signals to the flip-flop circuit;
providing a second plurality of clock signals generated by a controller to the flip-flop circuit; and
providing a second plurality of outputs corresponding to the second plurality of data signals and the second plurality of clock signals to move the first plurality of outputs through the FIFO device.

2. The method of claim 1, further comprising calculating a quantity of the second plurality of clock signals based on a quantity of storage locations of the FIFO device.

3. The method of claim 1, further comprising providing a notification, by a controller, to a memory resource associated with a memory device of a quantity of the second plurality of clock signals.

4. The method of claim 1, further comprising providing, by a controller, a notification to a memory resource associated with a memory device to ignore the second plurality of outputs.

5. The method of claim 1, wherein the second plurality of outputs comprise garbage data.

6. The method of claim 1, wherein the first plurality of outputs are provided to a memory resource when output from the FIFO device.

7. The method of claim 1, wherein the second plurality of clock signals are provided to a switch that receives first plurality of clock signals from a DQS processing circuit.

8. The method of claim 1, wherein the second plurality of data signals are not based on data stored by a memory resource.

9. An apparatus, comprising:
a memory device interface comprising:
a first flip-flop circuit to receive data signals from a data processing circuit;
a second flip-flop circuit to receive clock signals from a clock processing circuit;
a first first-in first-out (FIFO) device to receive a first output data from the first flip-flop circuit; and
a second FIFO device to receive a second output data from the second flip-flop circuit; and
a controller configured to:
receive the first output data from the first FIFO device;
receive the second output data from the second FIFO device;
generate additional clock signals to be provided to the second flip-flop to generate additional output data; and
notify a memory resource associated with the memory device to ignore the additional output data.

10. The apparatus of claim 9, wherein the controller is further configured to calculate a quantity of the additional clock signals based on a quantity of bits to be provided to the memory resource and a quantity of bits utilized by the first FIFO device and the second FIFO device.

11. The apparatus of claim 9, wherein the memory resource toggles the data signals to the data processing circuit and the controller toggles the clock signals to the clock processing circuit.

12. The apparatus of claim 9, wherein the controller is further configured to notify the memory resource associated with the memory device that the additional clock signals are provided to the second flip-flop.

13. The apparatus of claim 9, wherein the first flip-flop circuit and the second flip-flop circuit are positioned on a physical layer of the apparatus and the first FIFO device and the second FIFO device are positioned off the physical layer of the apparatus.

14. The apparatus of claim 9, wherein the first flip-flop circuit is coupled to the first FIFO device by a first plurality of pipeline stages and the second flip-flop circuit is coupled to the second FIFO device by a second plurality of pipeline stages.

15. The apparatus of claim 9, wherein the controller is configured to send the additional clock signals to the memory resource.

16. The apparatus of claim 15, wherein the memory resource is configured to flag data associated with the additional clock signals to the clock processing circuit as garbage data.

17. A system comprising:
a memory sub-system comprising a non-volatile memory device; and
a processing device coupled to the memory sub-system, wherein the processing device is configured to:
generate a plurality of clock signals that correspond to a plurality of data signals received from the non-volatile memory device;
identify an output value based on the plurality of data signals and the plurality of clock signals within a first-in first-out (FIFO) device;
generate additional clock signals when the non-volatile memory device has completed sending the plurality of data signals;
send the additional clock signals to the FIFO device; and
instruct the non-volatile memory device to provide additional data signals to the FIFO device based on the additional clock signals.

18. The system of claim 17, wherein the processing device is further configured to generate a data gap utilizing the additional clock signals.

19. The system of claim 17, wherein the additional clock signals push the output value out of the FIFO device.

20. The system of claim 17, wherein the processing device is further configured to:
identify a last clock signal from the non-volatile memory device; and
determine a quantity of additional clock signals to generate based on a quantity of bits within FIFO device and a size of the FIFO device.
